(19) United States
(12) Patent Application Publication
(10) Pub. No.: US 2025/0081584 A1
(43) Pub. Date: Mar. 6, 2025

(54) SEMICONDUCTOR DEVICE AND FABRICATING METHOD THEREOF

(71) Applicant: Fujian Jinhua Integrated Circuit Co., Ltd., Quanzhou City (CN)

(72) Inventor: Janbo Zhang, Quanzhou City (CN)

(73) Assignee: Fujian Jinhua Integrated Circuit Co., Ltd., Quanzhou City (CN)

(21) Appl. No.: 18/424,882

(22) Filed: Jan. 29, 2024

(30) Foreign Application Priority Data
Sep. 6, 2023 (CN) 202311146412.1

(51) Int. Cl. H01L 29/423; H01L 21/762; H10B 12/00

(52) U.S. Cl. CPC H10D 64/519; H01L 21/76224; H10B 12/00

(57) ABSTRACT

A semiconductor device and a fabricating method thereof includes a substrate, a plurality of active areas, a plurality of shallow trench isolations, and a plurality of word lines. The active areas are disposed in the substrate. The shallow trench isolations are disposed in the substrate, wherein each of the shallow trench isolations includes a first insulating layer and a second insulating layer stacked in sequence, the first insulating layer physically contacts one of the active areas. The word lines are separately disposed in the substrate to respectively overlap the active areas and the shallow trench isolations, wherein the word lines comprise at least one first word line, at least a portion of the second insulating layer is disposed between a sidewall of the at least one first word line and the first insulating layer of a corresponding one of the shallow trench isolations.

### BACKGROUND OF THE INVENTION

### 1. Field of the Invention

The present disclosure generally relates to a semiconductor device and a fabricating method thereof, and more particularly to a semiconductor device having an active structure and a shallow trench isolation and a fabricating method thereof.

### 2. Description of the Prior Art

With the miniaturization of semiconductor devices and the complexity of integrated circuits, the size of elements is continuously shrinking and the structure is constantly changing. Therefore, maintaining the performance of small-sized semiconductor elements is the standard purpose of the present industry. In the semiconductor fabricating process, most of the active regions are defined on the substrate as a bass element, and then, the required elements are further formed on the active regions. Generally, the active regions are plural patterns formed within the substrate through the photolithography and etching processes. However, due to the sized-shrinking requirements, the width of the active regions has been gradually reduced, and the pitch between the active regions has also been gradually reduced thereby, so that, the fabricating process of active regions encounters plenty limitations and challenges that fails to meet the practical product requirements.

### SUMMARY OF THE INVENTION

One object of the present disclosure is to provide a semiconductor device and a fabricating method thereof, in which, a shallow trench isolation having a multilayer structure is formed within the substrate, and buried word lines also formed within the substrate enable to intersect the multilayer structure of the shallow trench isolation, to avoid a serious step-height difference occurred on the buried word lines. With these arrangements, the semiconductor device and the fabricating method thereof is allowable to improve the structural reliability of the buried word lines, to avoid the possible structural defects, and to further enhance the operating performance of the semiconductor device.

To achieve the purpose described above, one embodiment of the present disclosure provides a semiconductor device including a substrate, a plurality of active areas, a shallow trench isolation and a plurality of word lines. The active areas are disposed in the substrate, and the active areas spaced apart from each other and arranged in a first direction. The shallow trench isolation is disposed in the substrate to surround the active areas, wherein the shallow trench isolation includes a first insulating layer and a plurality of second insulating layers. The first insulating layer physically contacts each of the active areas and surrounds each of the second insulating layers, and each of second insulating layers includes two lateral edges in the first direction. A plurality of word lines is disposed in the substrate, separately extending along a second direction and across the active areas and the shallow trench isolation, with the second direction being across and not perpendicular to the first direction. The word lines includes at least one first word line, and the at least one first word line interlaces ends portion of corresponding ones of the active areas to partially expose the lateral edges of a corresponding one of the second insulating layers adjacent to the end portions.

To achieve the purpose described above, one embodiment of the present disclosure provides another semiconductor device including a substrate, a plurality of active areas, a plurality of shallow trench isolations, and a plurality of word lines. The active areas are disposed in the substrate. The shallow trench isolations are disposed in the substrate, wherein each of the shallow trench isolations includes a first insulating layer and a second insulating layer stacked in sequence, the first insulating layer physically contacts one of the active areas. The word lines are separately disposed in the substrate to respectively overlap the active areas and the shallow trench isolations, wherein the word lines comprise at least one first word line, at least a portion of the second insulating layer is disposed between a sidewall of the at least one first word line and the first insulating layer of a corresponding one of the shallow trench isolations.

To achieve the purpose described above, one embodiment of the present disclosure provides a fabricating method of a semiconductor device including the following steps. Firstly, a substrate is provided, and a plurality of active areas is formed in the substrate. A plurality of shallow trench isolations is formed in the substrate, wherein each of the shallow trench isolations includes a first insulating layer and a second insulating layer stacked in sequence, and the first insulating layer physically contacts one of the active areas. A plurality of word lines is formed in the substrate, separately within the substrate to overlap the active areas and the shallow trench isolations. The word lines include at least one first word line, and at least a portion of the second insulating layer is disposed between a sidewall of the at least one first word line and the first insulating layer of a corresponding one of the shallow trench isolations.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 2 are schematic diagrams illustrating a semiconductor device according to a first embodiment in the present disclosure, in which:

FIG. 1 shows a top view of a semiconductor device in the first embodiment of the present disclosure; and

FIG. 2 shows cross-sectional views taken along cross lines A-A′ and B-B′ in FIG. 1.

FIG. 3 is a schematic diagram illustrating another cross-sectional view of a semiconductor device in the present disclosure.

FIG. 4 is a schematic diagram illustrating another cross-sectional view of a semiconductor device in the present disclosure.

FIG. 5 to FIG. 6 are schematic diagrams illustrating a semiconductor device according to a second embodiment in the present disclosure, in which:

FIG. 5 shows a top view of a semiconductor device in the second embodiment of the present disclosure; and

FIG. 6 shows a cross-sectional view taken along a cross line A-A′ in FIG. 5.

FIG. 7 to FIG. 8 are schematic diagrams illustrating a semiconductor device according to a third embodiment in the present disclosure, in which:

FIG. 7 shows a top view of a semiconductor device in the third embodiment of the present disclosure; and

FIG. 8 shows a cross-sectional view taken along a cross line A-A′ in FIG. 7.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different described in the following may be replaced, recombined, or mixed with one another to constitute another embodiment without departing from the spirit of the present disclosure.

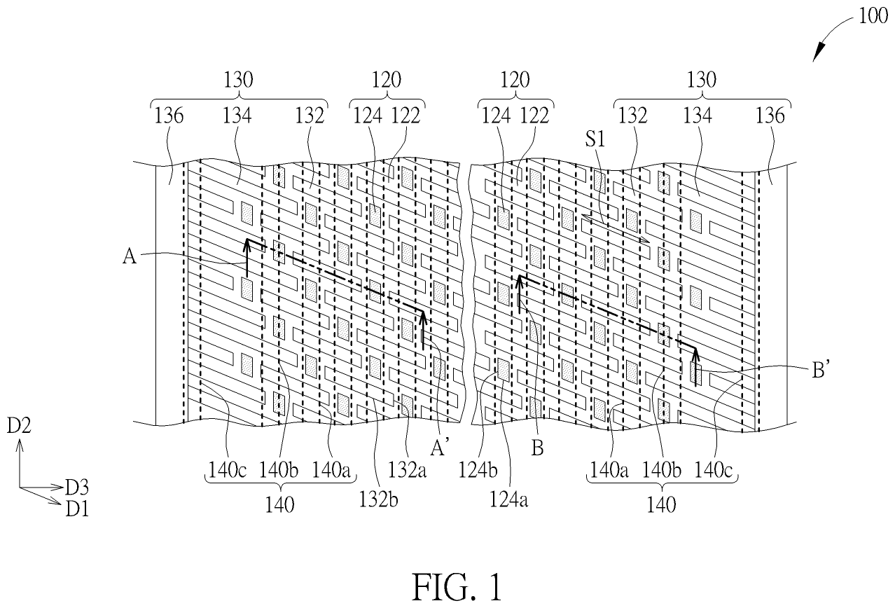

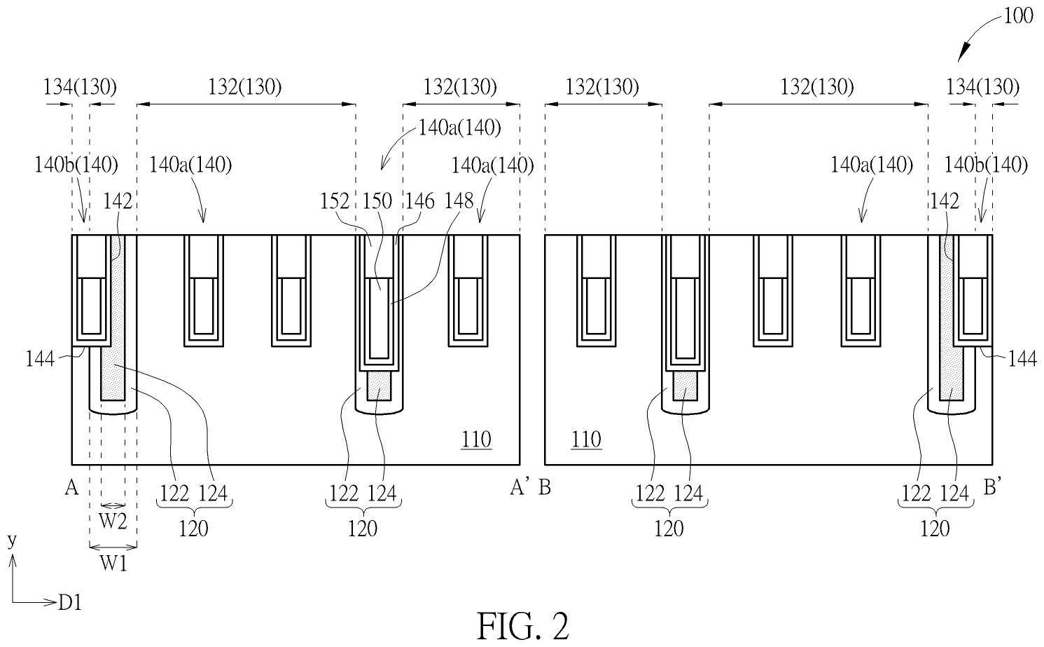

Please refer to FIG. 1 to FIG. 2, which illustrate a semiconductor device 100 according to a first embodiment of the present disclosure. Firstly, from a top view as shown in FIG. 1, the semiconductor device 100 includes a substrate 110, a plurality of active areas 132, a shallow trench isolation (STI) 120, and a plurality of word lines (WLs) 140. The substrate 110 for example includes a silicon substrate, a silicon containing substrate (such as SiC, SiGe), a silicon on insulator (SOI) substrate, or a substrate including any suitable material, but not limited thereto. Each of the active areas 132 are disposed within the substrate 110, being spaced apart from each other and arranged along a first direction D1, and each of the active areas 132 includes a length S1 in the first direction D1. The shallow trench isolation 120 is also disposed within the substrate 110, surrounding each of the active areas 132. The shallow trench isolation 120 further includes a first insulating layer 122 and a plurality of second insulating layers 124. The first insulating layer 122 for example includes an insulating material like silicon oxide or silicon oxynitride, to physically contact both of two long sides 132b of each active area 132 in the first direction D1, as well as two short side 132a of each active area 132 in another direction different from the first direction D1. The second insulating layers 124 are respectively disposed in the first insulating layer 122, and for example include an insulating material different from that of the first insulating layer 122, such as silicon nitride, silicon carbonitride, but not limited thereto. Accordingly, each of the second insulating layers 124 is surrounded by the first insulating layer 122. In other words, the shallow trench isolation 120 includes a multilayer structure including the first insulating layer 122 and the second insulating layers 124, wherein each of the second insulating layers 124 is disposed in the first insulating layer 122 and has two opposite lateral edges 124a in the first directions D1, and another two opposite lateral edges 124b in a second direction D2, with the lateral edges 124a being a boundary between each second insulating layer 124 and the first insulating layer 122 in the first direction D1, and with the another lateral edges 124b being a boundary between each second insulating layer 124 and the first insulating layer 122 in the second direction D2. The word lines 140 are also disposed within the substrate 110, with each of the word lines 140 separately extending along the second direction D2 to cross the active areas 132 and the shallow trench isolation 120. The second direction D2 is for example a vertical direction as shown in FIG. 1, and which is across and not perpendicular to the first direction D1.

It is noted that, the word lines 140 further include at least one first word line 140b, with the at least one first word line 140b across the end portions of several active areas 132 in the first direction D1, and overlapping the corresponding ones of the second insulating layers 124 closed to the end portions at the same time. The end portion is namely a portion where is closed to the short side 132a of each active area 132. That is, the at least one first word line 140b completely overlaps one of the two lateral edge 124b of each corresponding one of the second insulating layers 124, and partially overlaps the two lateral edges 124a of each corresponding one of the second insulating layers 124, thereby partially exposing the two lateral edges 124a of each corresponding one of the second insulating layers 124. Accordingly, the at least one first word line 140b arranged at the outer side enables to simultaneously interlace both of the shallow trench isolation 120 (including insulating materials) and the active areas 132 (including a semiconductor material) with obvious material differences therebetween, for improving the step-height issue. Precisely speaking, since the at least one first word line 140b physically contacts a semiconductor material and more than one insulating materials at the same time, it is sufficient to avoid the possible structural defects caused by a large step-height difference when the at least one first word line 140b interlaces the shallow trench isolation 120 and the active structure 130, by using a material buffering between various insulating materials of the multilayer structure of the shallow trench isolation 120. Then, the operating performance of the semiconductor device 100 will be improved thereby.

Further in view of FIG. 1, the semiconductor device 100 further includes a plurality of active areas 134 and an active boundary 136 within the substrate 110, with the active areas 132, the active areas 134, and the active boundary 136 together form an active structure 130 of the semiconductor device 100. Precisely speaking, the active boundary 136 is disposed outside all of the active areas 132 and all of the active areas 134, and which includes at least a portion extending along the second direction D2, but not limited thereto. The active areas 134 are disposed between the active areas 132 and the active boundary 136, to physically contact the active boundary 136, respectively. The active areas 134 are spaced apart from each to sequentially arrange in the first direction D1, and each of the active areas 134 includes a length either greater or smaller than that of the length S1. In one embodiment, the active areas 134 and the active areas 132 are sequentially arranged along the second direction D2 and the first direction D1 in a specific arrangement, such as an array arrangement shown in FIG. 1, such that, the adjacent ones of the active areas 132 and the active areas 134 are staggered arranged in the second direction D2, but not limited thereto. Accordingly, the shallow trench isolation 120 is disposed between each of the active areas 132, each of the active areas 134 and the active boundary 136, with the first insulating layer 122 physically contacts each of the active areas 132, each of the active areas 134, and the active boundary 136, and with each of the second insulating layers 124 being surrounded by the first insulating layer 122, between two adjacent ones of the active areas 132 in the first direction D1, or between one of the active areas 132 and one of the active areas 134 adjacent thereto. In a preferably embodiment, a shallow trench isolation (not shown in the drawings) may also be disposed to surround the entire active structure 130, to electrically isolate the active structure 130 from other elements, but not limited thereto.

Furthermore, the word lines 140 further includes a plurality of second word lines 140a and at least one third word lines 140c. Each of the second word lines 140a interlaces several active areas 132 and the shallow trench isolation 120 at the same time, to simultaneously interlace several second insulating layers 124 and to overlay the two lateral edges 124a and the two lateral edges 124b thereof. The third word line 140c does not interlace either any active area 132 or any second insulating layer 124, to only interlace several active areas 134, a portion of the active boundary 136 and the first insulating layer 122 of the shallow trench isolation 120. The second word lines 140a are arranged within a region with a relative higher elemental integration, such as a cell region, by a relative smaller pitch, and the at least one third word line 140c and the at least one first word line 140b are arranged in another region with a relative lower elemental integration, such as a periphery region, by a relative greater pitch, but not limited thereto. In one embodiment, the periphery region is for example disposed outside the cell region. For example, the periphery region is preferably disposed at two opposite sides of the cell region in a third direction D3, as being viewed from a top view of the semiconductor device 100 as shown in FIG. 1. The third direction D3 is perpendicular to the second direction D2. With these arrangements, the semiconductor device 100 preferably includes two first word lines 140b and two third word lines 140c, with the two first word lines 140c respectively disposed at two opposite sides of all of the second word lines 140a, and the two third word lines 140c respectively disposed at the outer sides of the two first word lines 140b, as shown in FIG. 1.

On the other hand, from a cross-sectional view as shown in FIG. 2, the semiconductor device 100 includes the substrate 110, a plurality of the active areas 132, a plurality of the shallow trench isolations 120, and a plurality of the word lines 140. The active areas 132 are spaced apart from each other, within the substrate 110. The shallow trench isolations 120 are also disposed within the substrate 110, respectively, wherein each of the shallow trench isolations 120 precisely includes the first insulating layer 122 and the second insulating layer 124 stacked sequentially in a horizontal direction (namely, the first direction D1 as shown in FIG. 1). The first insulating layer 122 of each shallow trench isolation 120 physically contacts each of the active areas 132, and includes a relative greater thickness W1 in the horizontal direction, and the second insulating layer 124 includes a relative smaller thickness W2, for example being about half to two thirds of the thickness W1, but not limited thereto. Each of the word lines 140 are separately disposed within the substrate 110, and which includes an interface layer 146, a metal barrier layer 148, a gate electrode 150 and a capping layer 152 stacked in sequence.

It is noted that, each of the word lines 140 overlaps a corresponding one of the active areas 132 or a corresponding one of the shallow trench isolations 120 in a vertical direction “y”. Each of the first word lines 140b partially overlaps a corresponding one of the active areas 134, and partially overlaps the first insulating layer 122 and the second insulating layer 124 of a corresponding one of the shallow trench isolations 120, so that, at least a portion of the second insulating layer 124 is disposed between a sidewall 142 of each of the first word lines 140b and the first insulating layer 122 of the corresponding one of the shallow trench isolations 120 adjacent thereto, physically contacting the sidewall 142 and a bottom surface 144 of each of the first word lines 140b at the same time. In other words, the second insulating layer 124 of the corresponding shallow trench isolation 120 partially overlaps each of the first word lines 140b, and partially not overlaps each of the first word lines 140b.

The second insulating layer 124 of the corresponding shallow trench isolation 120 where not overlapping each first word line 140b is disposed at the right side or the left side of each first word line 140b, between two first word lines 140b in the horizontal direction, as shown in FIG. 2. Each of the second word lines 140a overlaps a corresponding one of the active areas 132 or a corresponding one of the shallow trench isolations 120, with each second word line 140a overlapping the corresponding one of the shallow trench isolations 120 being disposed right above the second insulating layer 124 of the corresponding one of the shallow trench isolations 120 in the vertical direction “y”, and being completely overlapped with the second insulating layer 124 of the corresponding one of the shallow trench isolations 120 underneath. With these arrangements, the two first word lines 140b disposed at the outer sides of the second word lines 140a enable to physically contact the semiconductor material of the substrate 110, and two different insulating materials of the first insulating layer 122 and the second insulating layers 124, to improve the possible step-height issue easily occurred at the boundary between the active structure 130 and the shallow trench isolations 120, to avoid the structural defects derived from serious step-height difference, and to further improve the operating performance of the semiconductor device 100.

Following these, the semiconductor device 100 may be further in used on forming other semiconductor active elements, so as to further improve the efficiency of devices formed subsequently. For example, in the subsequent processes, a transistor (not shown in the drawings) may be formed on the active areas 132 of the semiconductor device 100 serving as a fin field-effect transistor (not shown in the drawings). Alternately, a transistor (not shown in the drawings) within the active areas 132 and a capacitor (not shown in the drawings) on the active areas 132 may be formed respectively, serving as a smallest memory cell of a dynamic random access memory, DRAM) device for receiving voltage information from bit lines (not shown in the drawings) and word lines 140.

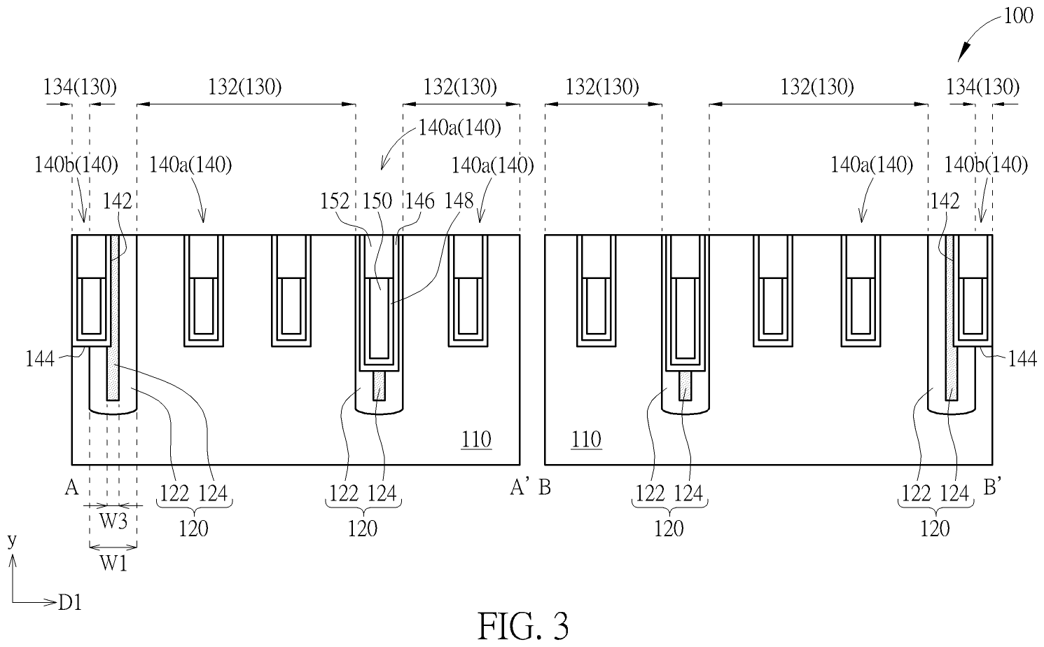

People skilled in the art should fully realize that the semiconductor device of the present disclosure may further includes other example or variations, and is not limited to the aforementioned embodiment, in order to meet the product requirements. For example, in another embodiment, the thicknesses of the first insulating layer 122 and/or the second insulating layer 124 may be further adjusted based on the practical product requirements, with a thickness W3 of the second insulating layer 124 in the horizontal direction being about one third to half of the thickness W1 of the first insulating layer 122, as shown in FIG. 3. Accordingly, the possible step-height issue between the shallow trench isolations 120 and the active structure 130 will be optimized thereby, to further improve the structural defects of the semiconductor device 100.

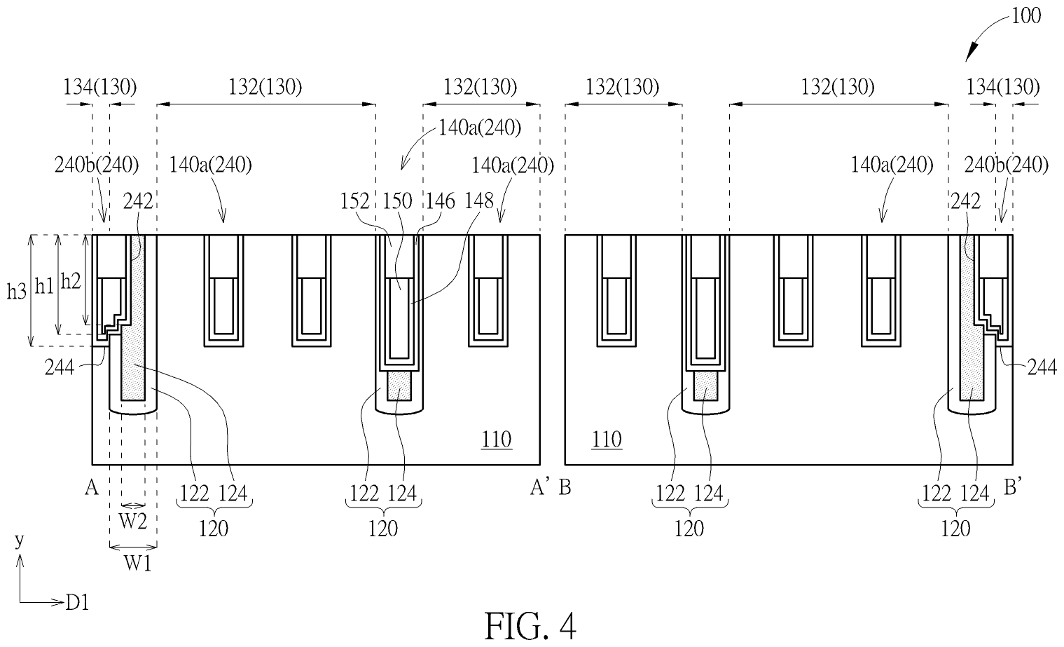

Furthermore, in another embodiment, a first word lines 240b disposed at one side of the second word lines 140a may further include a step-shaped bottom surface 244 as shown in FIG. 4, through adjusting the manufacturing process of the word lines 240. Precisely speaking, the first word line 240b partially overlaps the active areas 134 and partially overlaps the shallow trench isolation 120 (including the first insulating layer 122 and the second insulating layer 124) in the vertical direction “y” at the same time, and portions of the first word line 240b within the active areas 134 and within the shallow trench isolation 120 have various depths from the top surface of the substrate 110. The first word line 240b has a depth h1 within the first insulating layer 122 and has a depth h2 within the second insulating layer 124 of the shallow trench isolation 120, and has a depth h3 within the active areas 134, but not limited thereto. Accordingly, at least a portion of the second insulating layer 124 is also disposed between a sidewall 242 of each first word line 240b and the first insulating layer 122 of the corresponding one of the shallow trench isolation 120 adjacent thereto, which still enables to improve the possible step-height issue easily occurred at the boundary of the active structure 130 and the shallow trench isolations 120, and to avoid the structural defects derived from serious step-height difference. Then, the operating performance of the semiconductor device 100 may be effectively enhanced thereby.

In order to make people skilled in the art of the present disclosure easily understand the semiconductor device 100 of the present disclosure, the fabricating method of the semiconductor device 100 in the present disclosure will be further described below.

Firstly, the substrate 110 as shown in FIG. 1 and FIG. 2 is provided, and the active structure 130 and the shallow trench isolation 120 are formed within the substrate 110. In one embodiment, the formation of the active structure 130 is accomplished by performing a patterning process of the substrate 110, which includes the following steps. Firstly, a mask layer (not shown in the drawings) is formed on the substrate 110, with the mask layer including a plurality of patterns for defining the active areas 132, the active areas 134, and the active boundary 136, an etching process is performed through the mask layer, partially removing the substrate 110 to form at least one shallow trench (not shown in the drawings), two deposition processes are next performed to sequentially form a first insulating material (not shown in the drawings, for example including silicon oxide, or silicon oxynitride) and a second insulating material (not shown in the drawings, for example including silicon nitride, or silicon carbonitride) stacked sequentially in the shallow trench, and an etching back process is finally performed on the second insulating material and the first insulating material to form the shallow trench isolation 120, and also to define the active areas 132, the active areas 134 and the active boundary 136 at the same time. The active areas 132, the active areas 134 and the active boundary 136 together form the active structure 130. In another embodiment, a self-aligned double patterning (SADP) process or a self-aligned reverse patterning (SARP) process may be carried out to form the mask layer for defining the active areas 132, the active areas 134, and the active boundary 136, but not limited thereto. Then, a plurality of trenches (not shown in the drawings) is formed in the substrate 110, with the trenches parallel with each other in the second direction D2, and the interface layer 146 overlaying entire surfaces of each of the trenches, the metal barrier layer 148 overlaying surface of the lower portion of each of the trenches, the gate electrode 150 filled in the lower portion of each of the trenches, and the capping layer 152 filled in the upper portion of each of the trenches are formed in each of the trenches, thereby forming a plurality of word lines 140 within the substrate 110. Accordingly, the fabrication of the semiconductor device 100 is accomplished, and the word lines 140 include the first word lines 140b, the second word lines 140a and the third word lines 140c.

People skilled in the arts should easily realize the semiconductor device and the fabricating method thereof in the present disclosure are not limited to the aforementioned embodiment, and may further include other examples to meet practical product requirements. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

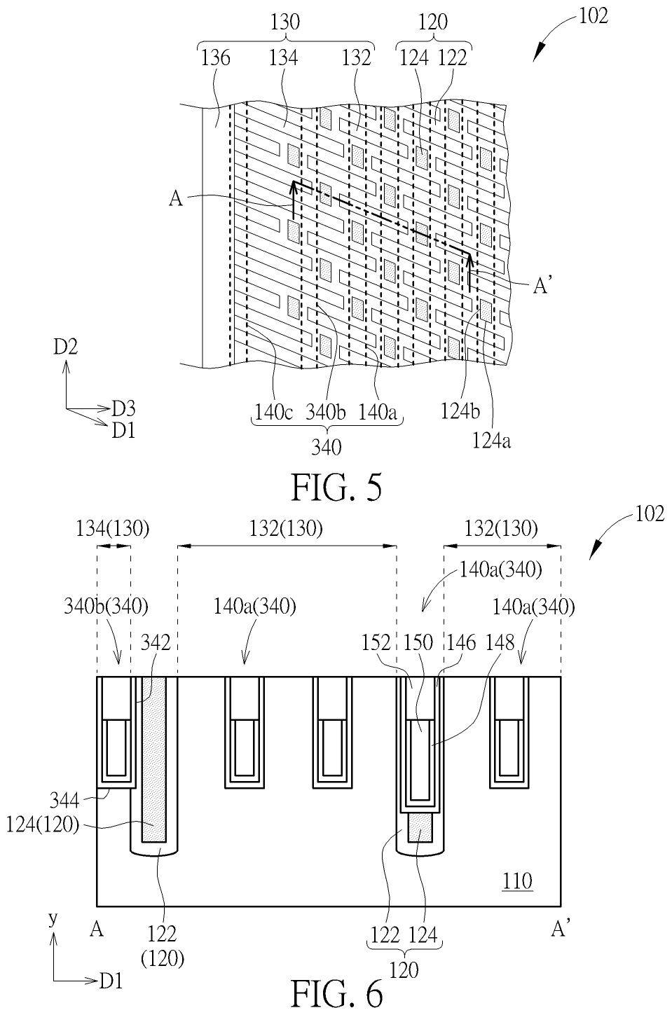

Please refer to FIG. 5 to FIG. 6, which illustrate a semiconductor device 102 according to a second embodiment of the present disclosure. The structure of the semiconductor device 102 of the present embodiment is substantially the same as that of the aforementioned first embodiment, and all the similarities of the two embodiments will not be redundantly described hereinafter. The difference between the present embodiment and the aforementioned first embodiment is mainly in that a first word line 340b simultaneously interlaces the end portions of corresponding ones of the active areas 132, without physically contacting any second insulating layer 124.

Firstly, from a top view as shown in FIG. 5, the first word line 340b simultaneously interlaces several active areas 132 and several active areas 134 of the active structure 130, and the first insulating layer 122 of the shallow trench isolation 120, and does not interlace any second insulating layer 124 closed to the end portions of the corresponding one of the active areas 132, thereby completely exposing two lateral edges 124a and two lateral edges 124b of each second insulating layer 124 closed to the end portions of the corresponding one of the active areas 132. On the other hand, from a cross-sectional view as shown in FIG. 6, the first word line 340b only overlaps the active area 134 and the first insulating layer 122 at the same time, without overlapping the second insulating layer 124 in the vertical direction “y”. That is, the first word line 340b only physical contacts the semiconductor material (the material of the substrate 110) and one insulating material (the material of the first insulating layer 122), and a portion of the second insulating layer 124 is still between a sidewall 342 of the first word line 340b and the first insulating layers 122 of the corresponding one of the shallow trench isolations 120 adjacent thereto. The second insulating layer 124 of the corresponding one of the shallow trench isolations 120 does not directly contact the sidewall 342 and the bottom surface 344 of the first word line 340b. Also, a portion of the first insulating layer 122 is further sandwiched between the sidewall 342 of the first word line 340b and the second insulating layer 124 of a corresponding one of the shallow trench isolations 120 adjacent thereto.

According to the semiconductor device 102 of the present embodiment, the first word line 340b disposed at the outer side of the second word lines 140a also enables to physically contact the semiconductor material (the material of the substrate 110) and the insulating material (the material of the first insulating layer 122) at the same time, to improve the possible step-height issue easily occurred at the boundary of the active structure 130 and the shallow trench isolations 120, and to avoid the structural defects derived from serious step-height difference. Then, the operating performance of the semiconductor device 102 will also be effectively enhanced thereby.

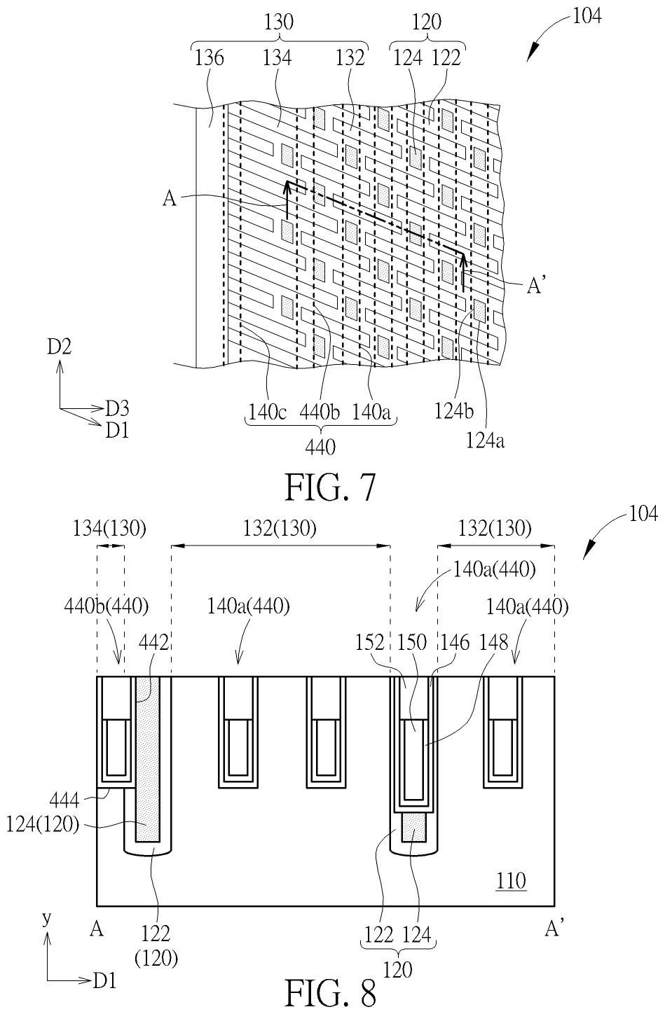

Please refer to FIG. 7 and FIG. 8, which illustrate a semiconductor device 104 according to a third embodiment of the present disclosure. The structure of the semiconductor device 104 of the present embodiment is substantially the same as that of the aforementioned first embodiment, and all the similarities of the two embodiments will not be redundantly described hereinafter. The difference between the present embodiment and the aforementioned first embodiment is mainly in that a first word line 440b simultaneously interlaces the end portions of the corresponding one of the active areas 132, to vertical align with lateral edges of the second insulating layer 124 of the corresponding ones of the shallow trench isolations 120.

Firstly, from a top view as shown in FIG. 7, the first word line 440b simultaneously interlaces several active areas 132 and several active areas 134 of the active structure 130, and the first insulating layer 122 of the shallow trench isolation 120, and does not interlace any second insulating layer 124 adjacent to the end portions of the corresponding one of the active areas 132, thereby completely exposing two lateral edges 124a of each second insulating layer 124 closed to the end potions of the corresponding one of the active areas 132. It is noted that, a sidewall of the first word line 440b is vertical aligned with the lateral edge 124b of each second insulating layer 124 closed to the end portions of the corresponding one of the active areas 132. On the other hand, from a cross-sectional view as shown in FIG. 8, the first word line 440b only overlaps the active area 134 and the first insulating layer 122 at the same time, without overlapping the second insulating layer 124 in the vertical direction “y”. The sidewall 442 of the first word line 440b overlaps the sidewall of the second insulating layers 124 of the corresponding one of the shallow trench isolations 120 adjacent thereto. That is, a portion of the second insulating layer 124 is also between the sidewall 442 of the first word line 440b and the first insulating layer 122 of the corresponding one of the shallow trench isolations 120 adjacent thereto, only physically contacting the sidewall 442 of the first word line 440b, without contacting the bottom surface 444 of the first word line 440b.

According to the semiconductor device 104 of the present embodiment, the first word line 440b disposed at the outer side of the second word lines 140a also enables to physically contact the semiconductor material (the material of the substrate 110) and various insulating materials (the materials of the first insulating layer 122 and the second insulating layer 124) at the same time, to improve the possible step-height issue easily occurred at the boundary of the active structure 130 and the shallow trench isolations 120, and to avoid the structural defects derived from serious step-height difference. Then, the operating performance of the semiconductor device 104 will also be effectively enhanced thereby.

Overall speaking, through the semiconductor device and the fabricating method thereof in the present disclosure, the shallow trench isolation having a multilayer structure is disposed within the substrate, such that, the buried word lines also formed within the substrate are allowable to cross over the multilayer structure of the shallow trench isolation, with the various insulating materials of the multilayer structure serving as a material buffering to avoid any possible structural defects of the buried word lines caused by a large step-height difference. With these arrangements, the semiconductor device and the fabricating method thereof enables to improve the structural reliability of the buried word lines, avoiding the possible the structural defects, and enhancing the operation of the semiconductor device thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of active areas disposed in the substrate, the active areas spaced apart from each other and arranged in a first direction;
a shallow trench isolation disposed in the substrate, comprising a first insulating layer and a plurality of second insulating layers, the first insulating layer physically contacting each of the active areas and surrounding each of the second insulating layers, and each of second insulating layers comprising two lateral edges in the first direction; and
a plurality of word lines, disposed in the substrate, the word lines separately extending along a second direction and across the active areas and the shallow trench isolation, the second direction being across and not perpendicular to the first direction, wherein the word lines comprises at least one first word line, the at least one first word line interlaces ends portion of corresponding ones of the active areas to partially expose the lateral edges of a corresponding one of the second insulating layers adjacent to the end portions.

2. The semiconductor device according to claim 1, wherein the at least one first word line interlaces the end portions of the active areas to completely expose the two lateral edges of the corresponding one of the second insulating layers adjacent to the end portions.

3. The semiconductor device according to claim 2, wherein the at least one first word line interlaces the end portions of the active areas to vertically align with a lateral edge of the corresponding one of the second insulating layers adjacent to the end portions, in the second direction.

4. The semiconductor device according to claim 2, wherein the at least one first word line interlaces the end portions of the active areas to completely expose a lateral edge of the corresponding one of the second insulating layers adjacent to the end portions, in the second direction.

5. The semiconductor device according to claim 1, wherein the word lines further comprise a plurality of second word lines, each of the word lines completely overlaps the two lateral edges of the corresponding one of the second insulating layers.

6. The semiconductor device according to claim 1, further comprising:
an active boundary, disposed in the substrate outside all of the active areas, wherein the word lines further comprise a third word line partially overlapping the active boundary.

7. The semiconductor device according to claim 6, wherein the third word line does not overlap any one of the second insulating layers.

8. A semiconductor device, comprising:
a substrate;
a plurality of active areas disposed in the substrate;
a plurality of shallow trench isolations disposed in the substrate, each of the shallow trench isolations comprising a first insulating layer and a second insulating layer stacked in sequence, the first insulating layer physically contacting one of the active areas; and
a plurality of word lines separately disposed in the substrate to respectively overlap the active areas and the shallow trench isolations, wherein the word lines comprise at least one first word line, at least a portion of the second insulating layer is disposed between a sidewall of the at least one first word line and the first insulating layer of a corresponding one of the shallow trench isolations.

9. The semiconductor device according to claim 8, wherein the at least one first word line partially overlaps the second insulating layer and the first insulating layer of the corresponding one of the shallow trench isolations.

10. The semiconductor device according to claim 9, wherein the second insulating layer of the corresponding one of the shallow trench isolations physically contacts the sidewall and a bottom surface of the at least one first word line.

11. The semiconductor device according to claim 9, wherein the at least one first word line comprises a step-shaped bottom surface.

12. The semiconductor device according to claim 9, wherein the at least one first word line where partially overlaps the second insulating layer of the corresponding one of the shallow trench isolations and where partially overlaps the first insulating layer of the corresponding one of the shallow trench isolations comprise different depths in the substrate.

13. The semiconductor device according to claim 8, wherein the at least one first word line only overlaps the first insulating layer of the corresponding one of the shallow trench isolations and the active areas.

14. The semiconductor device according to claim 13, wherein a sidewall of the second insulating layer of the corresponding one of the shallow trench isolations overlaps the sidewall of the at least one first word line.

15. The semiconductor device according to claim 13, wherein a portion of the first insulating layer of the corresponding one of the shallow trench isolations is sandwiched between the second insulating layer of the corresponding one of the shallow trench isolations and the sidewall of the at least one first word line.

16. The semiconductor device according to claim 13, wherein the at least one first word line where partially overlaps the first insulating layer of the corresponding one of the shallow trench isolations and where partially overlaps the second insulating layer of the corresponding one of the shallow trench isolations comprise different depths in the substrate.

17. The semiconductor device according to claim 8, wherein the word lines further comprise a plurality of second word lines, each of the second word lines completely overlaps the second insulating layer of a corresponding one of the shallow trench isolations in a vertical direction.

18. The semiconductor device according to claim 17, wherein the word lines further comprise two of the first word lines disposed at two opposite sides of all of the second word lines respectively, and the second insulating layer of the corresponding one of the shallow trench isolations where not overlaps the word lines is disposed between the two first word lines in a horizontal direction.

19. The semiconductor device according to claim 17, wherein each of the word lines comprises an interface layer, a metal barrier layer, a gate electrode, and a capping layer stacked in sequence.

20. A fabricating method of a semiconductor device, comprising:
providing a substrate;
forming a plurality of active areas in the substrate;
forming a plurality of shallow trench isolations in the substrate, each of the shallow trench isolations comprising a first insulating layer and a second insulating layer stacked in sequence, the first insulating layer physically contacting a sidewall of one of the active areas; and
forming a plurality of word lines in the substrate, the word lines separately within the substrate to overlap the active areas and the shallow trench isolations, wherein the word lines comprise at least one first word line, at least a portion of the second insulating layer is disposed between a sidewall of the at least one first word line and the first insulating layer of a corresponding one of the shallow trench isolations.
